(19) United States
(12) Patent Application Publication
(10) Pub. No.: US 2017/0133993 A1
(43) Pub. Date: May 11, 2017

(54) NONRECIPROCAL CIRCUIT ELEMENT

(71) Applicant: Murata Manufacturing Co., Ltd., Kyoto (JP)

(72) Inventors: Yuki Nakaike, Kyoto (JP); Reiji Nakajima, Kyoto (JP)

(21) Appl. No.: 15/412,508

(22) Filed: Jan. 23, 2017

Related U.S. Application Data
(63) Continuation of application No. PCT/JP2015/069390, filed on Jul. 6, 2015.

(30) Foreign Application Priority Data
Aug. 5, 2014 (JP) 2014-159630

(51) Int. Cl. H03H 1/00; H01P 1/38

(52) U.S. Cl. CPC H03H 1/00; H01P 1/38

(57) ABSTRACT

In a nonreciprocal circuit element (circulator), first, second, and third center conductors are disposed on a ferrite, to which a direct current magnetic field is applied, so as to be insulated from one another and so as to intersect with one another. One ends of the first, the second, and the third center conductors are defined as a first port, a second port, and a third port, respectively. The first port, the second port, and the third port are connected to a first terminal, a second terminal, and a third terminal, respectively. The other ends of the center conductors are connected to one another and are then connected to a ground. Capacitance elements are connected in parallel to the center conductors, respectively. Capacitors are provided in series or parallel to the first, the second, and the third center conductors, respectively.

This is a continuation of International Application No. PCT/JP2015/069390 filed on Jul. 6, 2015 which claims priority from Japanese Patent Application No. 2014-159630 filed on Aug. 5, 2014. The contents of these applications are incorporated herein by reference in their entireties.

### BACKGROUND

### Technical Field

The present disclosure relates to nonreciprocal circuit elements, and, more particularly, to a nonreciprocal circuit element such as an isolator or a circulator used in a microwave band.

Nonreciprocal circuit elements such as isolators and circulators have characteristics of transmitting a signal only in a direction determined in advance and transmitting no signal in the opposite direction. For example, circulators having the characteristics are used in transmission/receiving circuit portions of mobile communication devices such as cellular phones.

Patent Document 1 discloses, as this type of nonreciprocal circuit element, a lumped-constant circulator in FIG. 1 in which the other ends of a first center conductor, a second center conductor, and a third center conductor are connected to the ground via an inductance element and a capacitance element that are connected in series. However, this circulator cannot obtain satisfactory insertion loss characteristics over a wide band.

In the above-described circulator, on a substrate on which the first center conductor, the second center conductor, and the third center conductor are formed and a ferrite is mounted, the other ends of the first center conductor, the second center conductor, and the third center conductor are connected to a ground electrode of the substrate using respective independent ground connection terminals. Six terminals including three signal connection terminals, which are one ends of the center conductors, in addition to the ground connection terminals are provided in total. In order to provide lands used for connection to the six terminals on a mounting substrate, many restrictions are introduced on the design of the mounting substrate.

Patent Document 1: International Publication No. 2013/168771

### BRIEF SUMMARY

The present disclosure provides a lumped-constant nonreciprocal circuit element capable of improving insertion loss characteristics over a wide band. The present disclosure provides a nonreciprocal circuit element capable of reducing the number of connection terminals to improve the design flexibility of a mounting substrate.

In a nonreciprocal circuit element according to an embodiment of the present disclosure, a first center conductor, a second center conductor, and a third center conductor are disposed on a ferrite, to which a direct current magnetic field is applied, so as to be insulated from one another and so as to intersect with one another. One ends of the first center conductor, the second center conductor, and the third center conductor are defined as a first port, a second port, and a third port, respectively. The first port, the second port, and the third port are connected to a first terminal, a second terminal, and a third terminal, respectively. The other ends of the first center conductor, the second center conductor, and the third center conductor are connected to one another and are then connected to a ground. Respective capacitance elements are connected in parallel to the first center conductor, the second center conductor, and the third center conductor. Respective capacitors are provided in series or parallel to the first center conductor, the second center conductor, and the third center conductor.

The nonreciprocal circuit element is a lumped-constant nonreciprocal circuit element in which a first center conductor, a second center conductor, and a third center conductor are disposed on a ferrite, to which a direct current magnetic field is applied, so as to be insulated from one another and so as to intersect with one another. A high-frequency signal input from the second port is output from the first port, a high-frequency signal input from the first port is output from the third port, and a high-frequency signal input from the third port is output from the second port. The input-output relation of a high-frequency signal is reversed by inverting a direct current magnetic field applied from a permanent magnet.

Since respective capacitors are provided in series or parallel to the first center conductor, the second center conductor, and the third center conductor in the nonreciprocal circuit element, insertion loss characteristics are improved over a wide band.

In the nonreciprocal circuit element, on an upper surface and an undersurface of the ferrite, a plurality of conductive layers and a plurality of insulating layers can be laminated. The first center conductor, the second center conductor, and the third center conductor can be formed at the conductive layers. The other ends of the first center conductor, the second center conductor, and the third center conductor can be connected to the ground via another conductive layer. Since the other ends of the first center conductor, the second center conductor, and the third center conductor are combined at the other conductive layer, only one connection terminal is needed for them and the number of connection terminals is therefore reduced. This leads to an improvement in design flexibility of a mounting substrate.

According to the present disclosure, in a lumped-constant nonreciprocal circuit element, insertion loss characteristics can be improved over a wide band and the design flexibility of a mounting substrate can also be improved.

### BRIEF DESCRIPTION OF THE SEVERAL VIEWS OF THE DRAWINGS

FIG. 1 is an equivalent circuit diagram of a nonreciprocal circuit element (three-port circulator) according to a first embodiment of the present disclosure.

FIG. 2 is an exploded perspective view of a nonreciprocal circuit element according to the first embodiment.

FIG. 3 is an exploded perspective view of a center conductor assembly included in a nonreciprocal circuit element according to the first embodiment.

FIGS. 4A-4C are graphs illustrating the characteristics of a nonreciprocal circuit element according to the first embodiment.

FIG. 5 is an equivalent circuit diagram of a nonreciprocal circuit element (three-port circulator) according to a second embodiment of the present disclosure.

FIGS. 6A-6C are graphs illustrating the characteristics of a nonreciprocal circuit element according to the second embodiment.

FIG. 7 is a graph illustrating the characteristics of a nonreciprocal circuit element according to the second embodiment when the size of an electrode bundle is changed.

FIG. 8 is an exploded perspective view of a center conductor assembly included in a nonreciprocal circuit element (three-port circulator) according to a third embodiment of the present disclosure.

FIGS. 9A and 9B are graphs illustrating the characteristics of a nonreciprocal circuit element according to the third embodiment.

### DETAILED DESCRIPTION

A nonreciprocal circuit element according to an embodiment of the present disclosure will be described below with reference to the accompanying drawings. In the drawings, the same reference numeral is used to represent the same component or the same part so as to avoid repeated explanation.

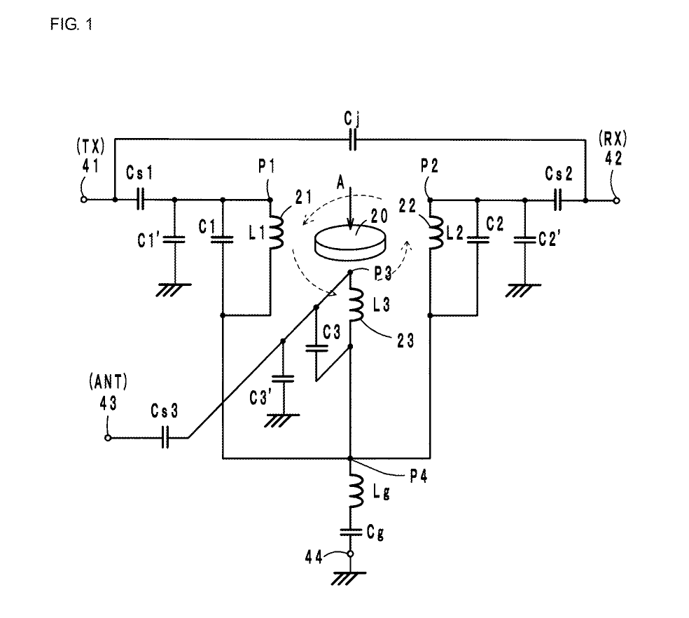

### First Embodiment, See FIGS. 1 to 4

A nonreciprocal circuit element according to the first embodiment is a three-port circulator having an equivalent circuit illustrated in FIG. 1. Specifically, a first center conductor 21 (L1), a second center conductor 22 (L2), and a third center conductor 23 (L3) are disposed on a ferrite 20, to which a direct current magnetic field is applied by a permanent magnet in a direction indicated by an arrow A, so as to be insulated from one another and so as to intersect with one another at predetermined angles. One end of the first center conductor 21 is defined as a first port P1, one end of the second center conductor is defined as a second port P2, and one end of the third center conductor 23 is defined as a third port P3.

The other ends of the respective center conductors 21, 22, and 23 are connected to one another (at a fourth port P4), and are then connected to the ground via an inductance element Lg and a capacitance element Cg that are connected in series. Capacitance elements C1, C2, and C3 are connected in parallel to the center conductors 21, 22, and 23, respectively. Capacitors C1′, C2′, and C3′ are provided in parallel to the center conductors 21, 22, and 23, respectively. The capacitor C1′ is connected between the port P1 and the ground, the capacitor C2′ is connected between the port P2 and the ground, and the capacitor C3′ is connected between the port P3 and the ground.

A capacitance element Cs1 is connected between the first port P1 and a first external connection terminal 41, a capacitance element Cs2 is connected between the second port P2 and a second external connection terminal 42, and a capacitance element Cs3 is connected between the third port P3 and a third external connection terminal 43. A capacitance element Cj is connected in series between the first external connection terminal 41 and the second external connection terminal 42.

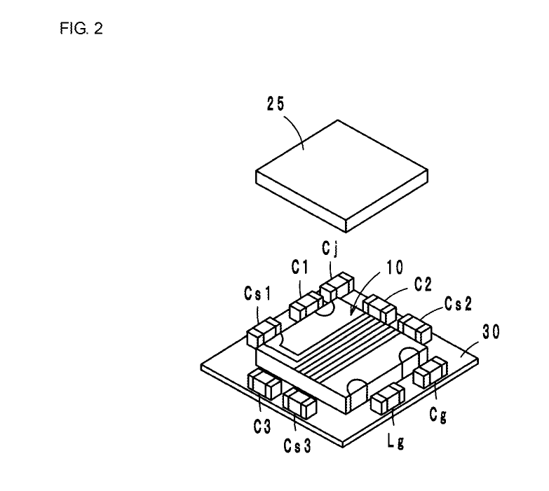

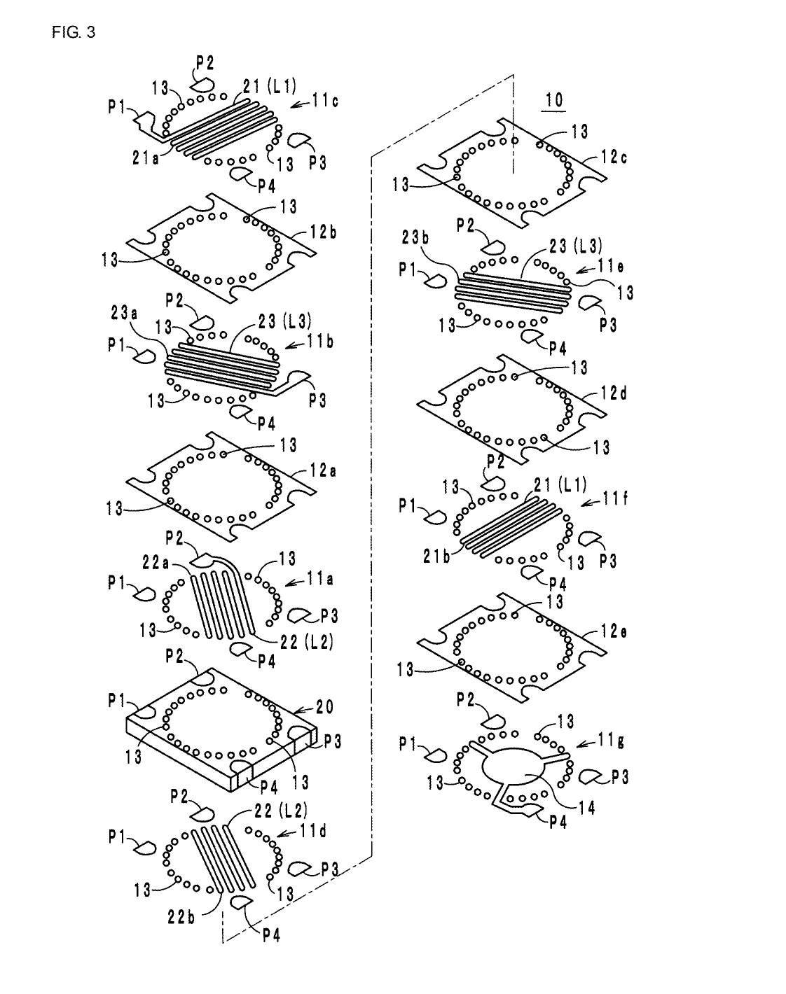

The three-port circulator having the above-described equivalent circuit includes a mounting substrate 30, a center conductor assembly 10, and a permanent magnet 25, as illustrated in FIGS. 2 and 3.

The center conductor assembly 10 includes conductive layers 11a to 11g and insulating layers 12a to 12e laminated on the upper surface and undersurface of the rectangular microwave ferrite 20 as illustrated in FIG. 3. Specifically, on the upper surface of the ferrite 20, the conductive layer 11a, the insulating layer 12a, the conductive layer 11b, the insulating layer 12b, and the conductive layer 11c are formed in this order. On the undersurface of the ferrite 20, the conductive layer 11d, the insulating layer 12c, the conductive layer 11e, the insulating layer 12d, the conductive layer 11f, the insulating layer 12e, and the conductive layer 11g are formed in this order.

The detailed description of the layers will be sequentially made from the top. The conductive layer 11c includes five conductors 21a forming the first center conductor 21, the connection terminal electrodes (ports) P1 to P4, and many via conductors 13. The connection terminal electrode P1 is connected to one end of the conductor 21a. The conductive layer 11b includes five conductors 23a forming the third center conductor 23, the connection terminal electrodes (ports) P1 to P4, and the many via conductors 13. The connection terminal electrode P3 is connected to one end of the conductor 23a. The conductive layer 11a includes five conductors 22a forming the second center conductor 22, the connection terminal electrodes (ports) P1 to P4, and the many via conductors 13. The connection terminal electrode P2 is connected to one end of the conductor 22a. The conductive layer 11d includes four conductors 22b forming the second center conductor 22, the connection terminal electrodes (ports) P1 to P4, and the many via conductors 13. The conductive layer 11e includes four conductors 23b forming the third center conductor 23, the connection terminal electrodes (ports) P1 to P4, and the many via conductors 13. The conductive layer 11f includes four conductors 21b forming the first center conductor 21, the connection terminal electrodes (ports) P1 to P4, and the many via conductors 13. The conductive layer 11g includes an electrode bundle 14 that is circular in plan view (viewed in a direction perpendicular to an extending surface of the insulating layer 12e), the connection terminal electrodes (ports) P1 to P4, and the many via conductors 13.

The conductors 21a and the conductors 21b are connected in a coil shape via the predetermined via conductors 13 to form the first center conductor 21. The conductors 22a and the conductors 22b are connected in a coil shape via the predetermined via conductors 13 to form the second center conductor 22. The conductors 23a and the conductors 23b are connected in a coil shape via the predetermined via conductors 13 to form the third center conductor 23. The electrode bundle 14 is disposed to overlap the intersection of the center conductors 21, 22, and 23 in the lamination direction of the conductive layers and the insulating layers. Between the electrode bundle 14 and the first center conductor 21, the capacitor C1′ is formed. Between the electrode bundle 14 and the second center conductor 22, the capacitor C2′ is formed. Between the electrode bundle 14 and the third center conductor 23, the capacitor C3′ is formed.

The conductive layer 11a to 11g can be formed as thin film conductors, thick film conductors, or conductive foils. The various capacitance elements and the various inductance elements are provided in the form of chip components (see FIG. 2). The insulating layers 12a to 12e can be made of photosensitive glass.

The connection terminal electrodes P1 to P4 and electrodes (not illustrated) used for the mounting of the various chip-type capacitance elements and the various chip-type inductance elements are formed on the upper surface of the mounting substrate 30. As illustrated in FIG. 2, by stacking the center conductor assembly 10 and the permanent magnet 25 and mounting them on the mounting substrate 30, a three-port circulator having the equivalent circuit illustrated in FIG. 1 is formed. Although not illustrated, on the undersurface of the mounting substrate 30, the first external connection terminal 41, the second external connection terminal 42, the third external connection terminal 43, and a ground connection terminal 44 are formed.

In a three-port circulator according to the first embodiment, a high-frequency signal input from the second external connection terminal 42 (the second port P2) is output from the first external connection terminal 41 (the first port P1), a high-frequency signal input from the first external connection terminal 41 (the first port P1) is output from the third external connection terminal 43 (the third port P3), and a high-frequency signal input from the third external connection terminal 43 (the third port P3) is output from the second external connection terminal 42 (the second port P2).

In a case where this three-port circulator is disposed between a transmission/receiving circuit portion and an antenna in a cellular phone, the first external connection terminal 41 is connected to a transmission circuit, the second external connection terminal 42 is connected to a receiving circuit, and the third external connection terminal 43 is connected to the antenna so that a signal is not transmitted from the second external connection terminal 42 to the first external connection terminal 41.

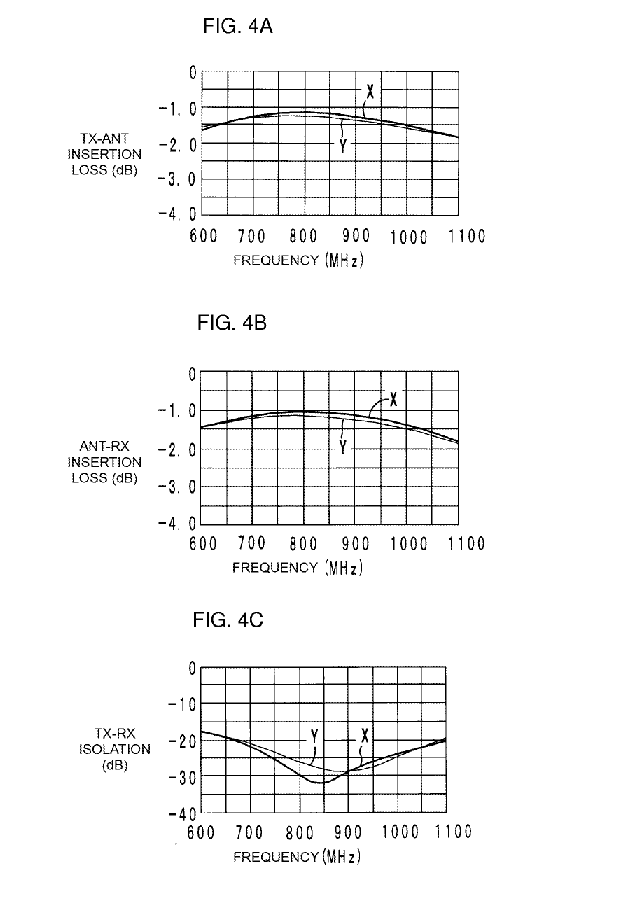

In this three-port circulator, insertion loss characteristics at a path from the first external connection terminal (TX) 41 to the third external connection terminal (ANT) 43 are represented by a curve X in FIG. 4A, and insertion loss characteristics at a path from the third external connection terminal (ANT) 43 to the second external connection terminal (RX) 42 are represented by a curve X in FIG. 4B. In FIGS. 4A and 4B, curves Y represent characteristics obtained in a case where the capacitors C1′, C2′, and C3′ are not formed as comparative examples. As is apparent from the comparison between the curves X and Y, the characteristics X obtained in a case where the capacitors C1′, C2′, and C3′ are formed show an improvement in the amount of attenuation over a wide band. By employing the arrangement of the capacitors C1′, C2′, and C3′ according to the first embodiment, capacitance optimization can be performed for the center conductors 21, 22, and 23. Accordingly, insertion loss characteristics can be improved over a wider band.

Isolation characteristics at a path from the first external connection terminal (TX) 41 to the second external connection terminal (RX) 42 are represented by a curve X in FIG. 4C. In this drawing, a curve Y represents characteristics obtained in a case where the capacitors C1′, C2′, and C3′ are not formed as a comparative example. As is apparent from the comparison between the curves X and Y, degradation in isolation characteristics does not occur.

The other ends of the first center conductor 21, the second center conductor 22, and the third center conductor 23 are connected to the single connection terminal electrode P4 at a single conductive layer (the electrode bundle 14). As a result, in the center conductor assembly 10, only four connection terminal electrodes P1 to P4 are needed. Thus, the number of connection terminal electrodes can be reduced and the design flexibility of the mounting substrate 30 is improved.

In order to obtain a satisfactory insertion loss over a wide band in this three-port circulator, it is necessary to increase the accuracy of matching between a magnetic rotor including the center conductor assembly 10 and the permanent magnet 25 and each of the input/output ports P1, P2, and P3. By making a series connection and a parallel connection using the capacitors C1′, C2′, and C3′ and using these connections in combination, the matching accuracy can be increased. In this embodiment, the capacitors C1′, C2′, and C3′ are provided in parallel to the center conductors 21, 22, and 23, respectively. The combination of these parallel connections and connections to the capacitance element Cs1, Cs2, and Cs3 can achieve matching with high accuracy at the input/output ports P1, P2, and P3. As a result, the accuracy of matching between the magnetic rotor and each of the input/output ports P1, P2, and P3 can be increased and satisfactory insertion loss characteristics can be obtained over a wide band.

Especially in a case where the center conductors 21, 22, and 23 are laminated on the ferrite 20 to form the center conductor assembly 10 like in this embodiment, the accuracy of matching between the magnetic rotor and an input/output port tends to decrease depending on the lamination order of the center conductors 21, 22, and 23. The capacitors C1′, C2′, and C3′ can compensate for the decrease in the matching accuracy.

In this three-port circulator, the connection of the other ends of the center conductors 21, 22, and 23 to the ground via a series resonance circuit including the inductance element Lg and the capacitance element Cg also contributes to the acquisition of insertion loss characteristics over a wide band. The capacitance element Cj contributes to an improvement in insertion loss characteristics at a path from the first external connection terminal 41 to the third external connection terminal 43.

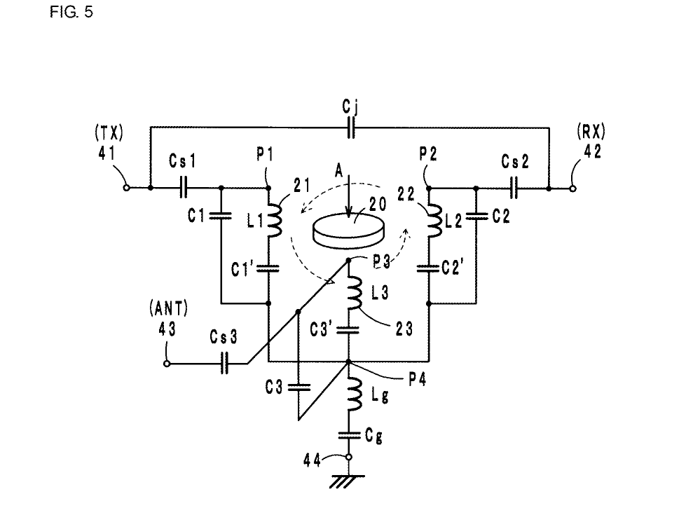

### Second Embodiment, See FIGS. 5 to 7

A nonreciprocal circuit element according to a second embodiment of the present disclosure is a three-port circulator including an equivalent circuit illustrated in FIG. 5, and the circuit configuration thereof is basically the same as that according to the first embodiment illustrated in FIG. 1 except that the other ends of the respective center conductors 21, 22, and 23 are connected to one another (at the fourth port P4) via the capacitors C1′, C2′, and C3′, respectively, and are then connected to the ground via the inductance element Lg and the capacitance element Cg that are connected in series.

The three-port circulator having such an equivalent circuit includes the mounting substrate 30, the center conductor assembly 10, and the permanent magnet 25 illustrated in FIGS. 2 and 3. The center conductor assembly 10 according to the first embodiment is used. Like in the first embodiment, the capacitor C1′ is formed between the electrode bundle 14 and the center conductor 21, the capacitor C2′ is formed between the electrode bundle 14 and the center conductor 22, and the capacitor C3′ is formed between the electrode bundle 14 and the center conductor 23.

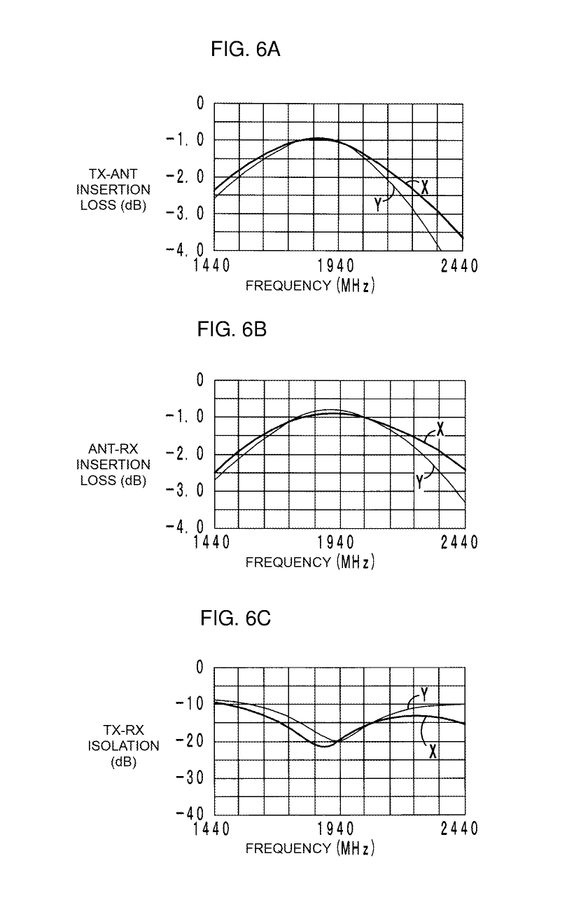

A three-port circulator according to the second embodiment, in which a high-frequency signal is transmitted as described in the first embodiment, is disposed between a transmission/receiving circuit portion and an antenna in, for example, a cellular phone. Insertion loss characteristics at a path from the first external connection terminal (TX) 41 to the third external connection terminal (ANT) 43 are represented by a curve X in FIG. 6A, and insertion loss characteristics at a path from the third external connection terminal (ANT) 43 to the second external connection terminal (RX) 42 are represented by a curve X in FIG. 6B. In FIGS. 6A and 6B, curves Y represent characteristics obtained in a case where the capacitors C1′, C2′, and C3′ are not formed as comparative examples. As is apparent from the comparison between the curves X and Y, the characteristics X obtained in a case where the capacitors C1′, C2′, and C3′ are formed show an improvement in the amount of attenuation over a wide band. By employing the arrangement of the capacitors C1′, C2′, and C3′ according to the second embodiment, capacitance optimization can be performed for the center conductors 21, 22, and 23. Accordingly, insertion loss characteristics can be improved over a wider band.

Isolation characteristics at a path from the first external connection terminal (TX) 41 to the second external connection terminal (RX) 42 are represented by a curve X in FIG. 6C. In this drawing, a curve Y represents characteristics obtained in a case where the capacitors C1′, C2′, and C3′ are not formed as a comparative example. As is apparent from the comparison between the curves X and Y, degradation in isolation characteristics does not occur.

The other ends of the first center conductor 21, the second center conductor 22, and the third center conductor 23 are connected to the single connection terminal electrode P4 at a single conductive layer (the electrode bundle 14). As a result, in the center conductor assembly 10, only four connection terminal electrodes P1 to P4 are needed. Thus, the number of connection terminal electrodes can be reduced and the design flexibility of the mounting substrate 30 is improved.

The reason why insertion loss characteristics can be obtained over a wide band in this three-port circulator is that the capacitance elements Cs1, Cs2, and Cs3 are connected to the ports P1, P2, and P3, respectively, and the other ends of the center conductors 21, 22, and 23 are connected to the ground via a series resonance circuit including the inductance element Lg and the capacitance element Cg. The capacitance element Cj contributes to an improvement in insertion loss characteristics at a path from the first external connection terminal 41 to the third external connection terminal 43.

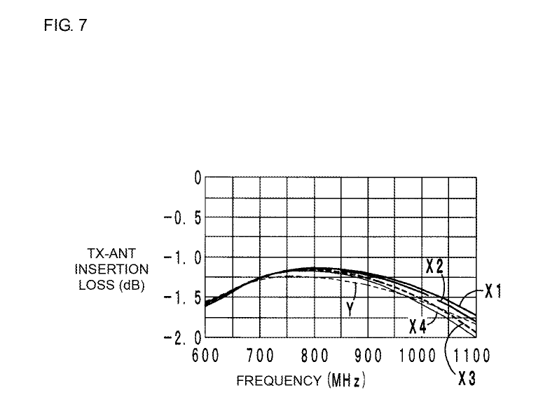

### (Size of Electrode Bundle, See FIG. 7)

The characteristics of the above-described nonreciprocal circuit element according to the second embodiment were simulated while setting the diameter of the electrode bundle 14, which is circular in plan view, to 0.3 mm, 0.4 mm, 0.5 mm, and 0.6 mm. FIG. 7 illustrates insertion loss characteristics at a path from the first external connection terminal (TX) 41 to the third external connection terminal (ANT) 43. The intersection of the center conductors 21, 22, and 23 in plan view is substantially circular in shape and has the diameter of 0.5 mm. This intersection overlaps the electrode bundle 14 in plan view.

Referring to FIG. 7, curves X1, X2, X3, and X4 represent insertion loss characteristics obtained in a case where the diameter of the electrode bundle 14 is set to 0.6 mm, 0.5 mm, 0.4 mm, and 0.3 mm, respectively. A curve Y represents characteristics obtained in a case where the electrode bundle 14 is not disposed, that is, the capacitors C1′, C2′, and C3′ are not formed as a comparative example. When the electrode bundle 14 is disposed, good characteristics can be obtained with any diameter. Especially in a case where the area (the diameter of 0.6 mm) of the electrode bundle 14 is relatively larger than that of the intersection of the center conductors 21, 22, and 23, an improvement in insertion loss characteristics is remarkable (see the curve X1 in FIG. 7).

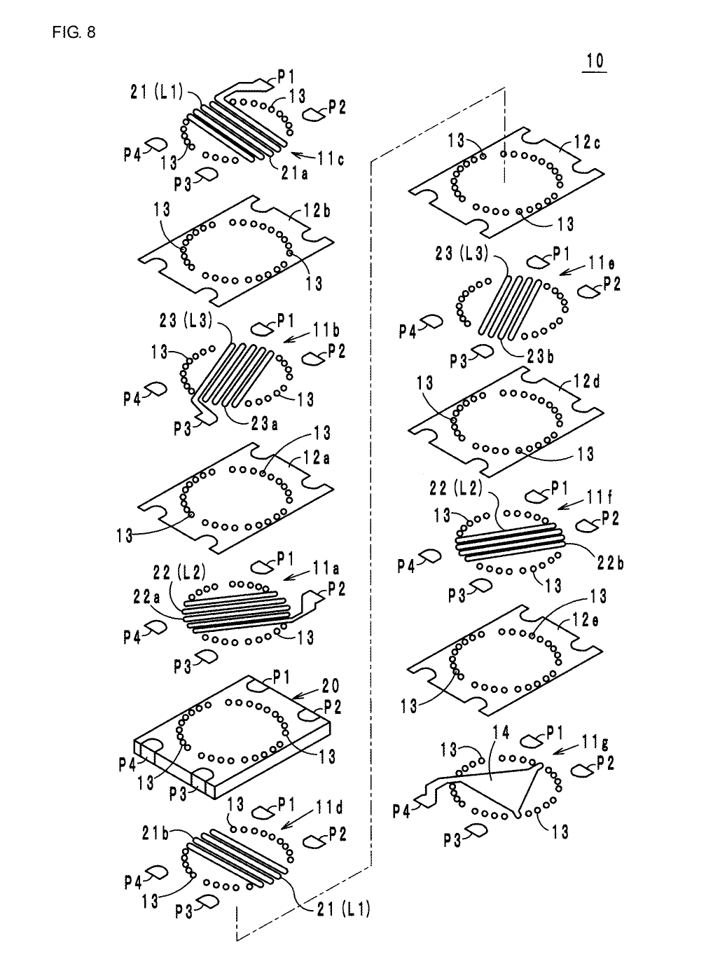

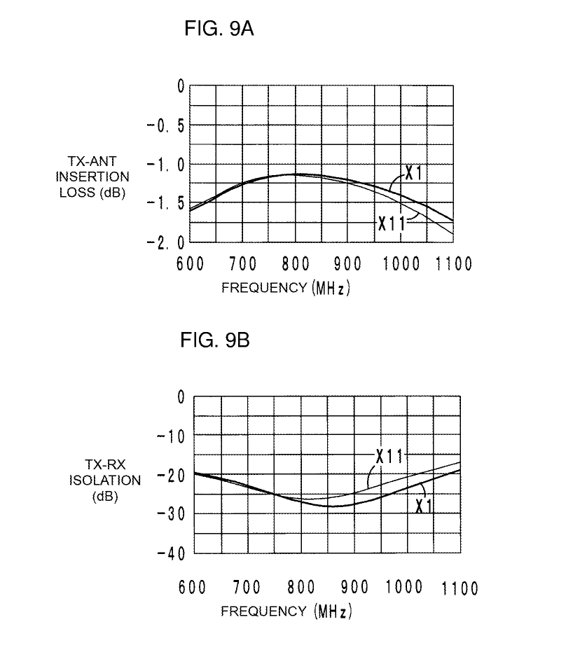

### Third Embodiment, See FIGS. 8 and 9

FIG. 8 illustrates the center conductor assembly 10 in a nonreciprocal circuit element according to the third embodiment. An equivalent circuit according to the third embodiment is the same as that according to the second embodiment illustrated in FIG. 5. Specifically, the capacitors C1′, C2′, and C3′ are connected in series to the center conductors 21, 22, and 23, respectively. The center conductor assembly 10 also includes the conductive layers 11a to 11g and the insulating layers 12a to 12e laminated on the upper surface and undersurface of the rectangular microwave ferrite 20 as illustrated in FIG. 3. Specifically, on the upper surface of the ferrite 20, the conductive layer 11a, the insulating layer 12a, the conductive layer 11b, the insulating layer 12b, and the conductive layer 11c are formed in this order. On the undersurface of the ferrite 20, the conductive layer 11d, the insulating layer 12c, the conductive layer 11e, the insulating layer 12d, the conductive layer 11f, the insulating layer 12e, and the conductive layer 11g are formed in this order.

The detailed description of the layers will be sequentially made from the top. The conductive layer 11c includes the five conductors 21a forming the first center conductor 21, the connection terminal electrodes (ports) P1 to P4, and the many via conductors 13. The connection terminal electrode P1 is connected to one end of the conductor 21a. The conductive layer 11b includes the five conductors 23a forming the third center conductor 23, the connection terminal electrodes (ports) P1 to P4, and the many via conductors 13. The connection terminal electrode P3 is connected to one end of the conductor 23a. The conductive layer 11a includes the five conductors 22a forming the second center conductor 22, the connection terminal electrodes (ports) P1 to P4, and the many via conductors 13. The connection terminal electrode P2 is connected to one end of the conductor 22a. The conductive layer 11d includes the four conductors 21b forming the first center conductor 21, the connection terminal electrodes (ports) P1 to P4, and the many via conductors 13. The conductive layer 11e includes the four conductors 23b forming the third center conductor 23, the connection terminal electrodes (ports) P1 to P4, and the many via conductors 13. The conductive layer 11f includes the four conductors 22b forming the second center conductor 22, the connection terminal electrodes (ports) P1 to P4, and the many via conductors 13. The conductive layer 11g includes the electrode bundle 14 that is substantially triangular in shape, the connection terminal electrodes (ports) P1 to P4, and the many via conductors 13.

The conductors 21a and the conductors 21b are connected in a coil shape via the predetermined via conductors 13 to form the first center conductor 21. The conductors 22a and the conductors 22b are connected in a coil shape via the predetermined via conductors 13 to form the second center conductor 22. The conductors 23a and the conductors 23b are connected in a coil shape via the predetermined via conductors 13 to form the third center conductor 23. The electrode bundle 14 is disposed directly below the intersection of the center conductors 21, 22, and 23, so that the capacitor C1′ is formed between the electrode bundle 14 and the first center conductor 21, the capacitor C2′ is formed between the electrode bundle 14 and the second center conductor 22, and the capacitor C3′ is formed between the electrode bundle 14 and the third center conductor 23. This embodiment is the same as the second embodiment in the point that the capacitors C1′, C2′, and C3′ are added to a circulator circuit in terms of a distributed constant.

A circulator according to the third embodiment basically has the same function as a circulator according to the second embodiment and obtains the same operational effect. A curve X11 in FIG. 9A represents insertion loss characteristics and a curve X11 in FIG. 9B represents isolation characteristics in a case where the electrode bundle 14 is triangular in shape. FIGS. 9A and 9B also illustrate, for reference, the curves X1 representing characteristics obtained in a case where the electrode bundle 14 according to the second embodiment with the diameter of 0.6 mm is used. The most remarkable improvements in insertion loss characteristics and isolation characteristics can be achieved in a case where the electrode bundle 14 is circular in shape. However, even in a case where the electrode bundle 14 is triangular in shape, a good improvement can be achieved. Values set for respective elements at the time of simulation of characteristics illustrated in FIGS. 9A and 9B in the third embodiment are the same as those set in the second embodiment.

### OTHER EMBODIMENTS

A nonreciprocal circuit element according to the present disclosure is not limited to the above-described embodiments, and various changes can be made to these embodiments without departing from the scope of the present disclosure.

For example, a center conductor may have any configuration and any shape. As the capacitors C1′, C2′, and C3′, chip-type capacitance elements may be disposed on a mounting substrate. As various capacitance elements including the elements C1, C2, and C3 and an inductance element such as the element Lg, chip-type elements may be disposed on a mounting substrate. Alternatively, they may be included in a mounting substrate as internal conductors. An electrode bundle may have any shape and any area. For example, an electrode bundle may be circular, substantially triangular, oval, or polygonal in shape.

### REFERENCE SIGNS LIST

10 center conductor assembly
14 electrode bundle
20 ferrite
21 first center conductor
22 second center conductor
23 third center conductor
25 permanent magnet
41, 42, 43, and 44 terminal
P1, P2, P3, and P4 port
C1, C2, and C3 capacitance element
Lg inductance element
Cg, Cj, Cs1, Cs2, and Cs3 capacitance element
C1′, C2′, and C3′ capacitor

1. A nonreciprocal circuit comprising:
a ferrite, wherein a direct current magnetic field is applied to the ferrite;
a first center conductor, a second center conductor, and a third center conductor disposed on the ferrite;
respective first capacitance elements connected in parallel with the first center conductor, the second center conductor, and the third center conductor; and
respective capacitors connected in parallel with the first center conductor, the second center conductor, and the third center conductor,
wherein the first center conductor, the second center conductor, and the third center conductor are insulated from one another and intersect with one another,
wherein a first end of the first center conductor represents a first port and is connected to a first terminal,
wherein a first end of the second center conductor represents a second port and is connected to a second terminal, wherein a first end of the third center conductor represents a third port and is connected to a third terminal,
wherein second ends of each of the first center conductor, the second center conductor, and the third center conductor are connected to each other at a fourth port, the fourth port being connected to ground.

2. The nonreciprocal circuit element according to claim 1, wherein the respective capacitors and first capacitance elements are connected in parallel to each other.

3. The nonreciprocal circuit element according to claim 1, wherein respective second capacitance elements are connected in series between the first port and the first terminal, the second port and the second terminal, and the third port and the third terminal.

4. The nonreciprocal circuit element according to claim 1, wherein an inductance element and a capacitance element connected in series between ground and the fourth port.

5. The nonreciprocal circuit element according to claim 1, wherein an insertion loss capacitance element is connected in series between the first terminal and the second terminal.

6. The nonreciprocal circuit element according to claim 1,
wherein, a plurality of conductive layers and a plurality of insulating layers are laminated on an upper surface and an undersurface of the ferrite, and
wherein the first center conductor, the second center conductor, and the third center conductor are formed on the conductive layers, and the second ends of the first center conductor, the second center conductor, and the third center conductor are connected to the ground via a different conductive layer.

7. The nonreciprocal circuit element according to claim 6,
wherein the ferrite, the conductive layers, and the insulating layers form a laminate, and
wherein the first terminal, the second terminal, the third terminal, and a fourth terminal connected to the different conductive layer are formed on a side surface of the laminate.

8. The nonreciprocal circuit element according to claim 6, wherein the different conductive layer and an intersection of the first center conductor, the second center conductor, and the third center conductor overlap in a plan view.

9. The nonreciprocal circuit element according to claim 6, wherein the different conductive layer is circular or oval in shape in a plan view.

10. The nonreciprocal circuit element according to claim 6, wherein an area of the different conductive layer in plan view is larger than an area of the intersection of the first center conductor, the second center conductor, and the third center conductor in the plan view.

11. A nonreciprocal circuit comprising:
a ferrite, wherein a direct current magnetic field is applied to the ferrite;
a first center conductor, a second center conductor, and a third center conductor disposed on the ferrite;
respective first capacitance elements connected in parallel with the first center conductor, the second center conductor, and the third center conductor; and
respective capacitors connected in series with the first center conductor, the second center conductor, and the third center conductor,
wherein the first center conductor, the second center conductor, and the third center conductor are insulated from one another and intersect with one another,
wherein a first end of the first center conductor represents a first port and is connected to a first terminal,
wherein a first end of the second center conductor represents a second port and is connected to a second terminal,
wherein a first end of the third center conductor represents a third port and is connected to a third terminal,
wherein second ends of each of the first center conductor, the second center conductor, and the third center conductor are connected to first ends of the respective capacitors and second ends of the respective capacitors are connected to each other at a fourth port, the fourth port being connected to ground.

12. The nonreciprocal circuit element according to claim 1, wherein the respective capacitors and first capacitance elements are connected in parallel to each other.

13. The nonreciprocal circuit element according to claim 1, wherein respective second capacitance elements are connected in series between the first port and the first terminal, the second port and the second terminal, and the third port and the third terminal.

14. The nonreciprocal circuit element according to claim 1, wherein an inductance element and a capacitance element connected in series between ground and the fourth port.

15. The nonreciprocal circuit element according to claim 1, wherein an insertion loss capacitance element is connected in series between the first terminal and the second terminal.

16. The nonreciprocal circuit element according to claim 1,
wherein, a plurality of conductive layers and a plurality of insulating layers are laminated on an upper surface and an undersurface of the ferrite, and
wherein the first center conductor, the second center conductor, and the third center conductor are formed on the conductive layers, and the second ends of the first center conductor, the second center conductor, and the third center conductor are connected to the ground via a different conductive layer.

17. The nonreciprocal circuit element according to claim 6,
wherein the ferrite, the conductive layers, and the insulating layers form a laminate, and
wherein the first terminal, the second terminal, the third terminal, and a fourth terminal connected to the different conductive layer are formed on a side surface of the laminate.

18. The nonreciprocal circuit element according to claim 6, wherein the different conductive layer and an intersection of the first center conductor, the second center conductor, and the third center conductor overlap in a plan view.

19. The nonreciprocal circuit element according to claim 6, wherein the different conductive layer is circular or oval in shape in a plan view.

20. The nonreciprocal circuit element according to claim 6, wherein an area of the different conductive layer in a plan view is larger than an area of the intersection of the first center conductor, the second center conductor, and the third center conductor in the plan view.
